(19) United States
(12) Patent Application Publication
(10) Pub. No.: US 2012/0168936 A1
(43) Pub. Date: Jul. 5, 2012

(54) MULTI-CHIP STACK PACKAGE STRUCTURE AND FABRICATION METHOD THEREOF

(75) Inventors: Pin-Cheng Huang, Taichung (TW); Chun-Chieh Chao, Taichung (TW); Chi-Hsin Chiu, Taichung (TW)

(73) Assignee: SILICONWARE PRECISION INDUSTRIES CO., LTD., Taichung (TW)

(21) Appl. No.: 13/243,646

(22) Filed: Sep. 23, 2011

(30) Foreign Application Priority Data
Dec. 31, 2010 (TW) 99147157

(51) Int. Cl. H01L 23/498; H01L 21/56

(52) U.S. Cl. 257/737; 438/122; 257/E23.068; 257/E21.502

(57) ABSTRACT

A multi-chip stack package structure includes: an inner-layer heat sink having a first surface and a second surface opposing one another and having a plurality of conductive vias penetrating the first surface and the second surface; a first chip disposed on the first surface of the inner-layer heat sink; and a second chip disposed on the second surface of the inner-layer heat sink. Thereby, a heat-dissipating path is provided within inner-layers of the multi-chip stack package structure, and the rigidity of the overall structure is enhanced.

### BACKGROUND OF THE INVENTION

1. Field of the Invention

The present invention relates to package structures and fabrication methods thereof, and, more particularly, to a multi-chip stack package structure and a fabrication method thereof.

2. Description of Related Art

Electronic products are becoming lighter, thinner, shorter and smaller. Meanwhile, demand continues for electronic products with high efficiency, low power consumption and multi-functionality. To meet such demand, a semiconductor package with a plurality of semiconductor chips horizontally mounted on a packaging substrate has been developed. However, due to the limited size of the packaging substrate, the number of semiconductor chips that can be horizontally mounted on the packaging substrate is quite limited. Accordingly, a multi-chip stack structure has also been developed to reduce the occupied area of the packaging substrate and shorten the transmission path, thereby achieving high efficiency, lower power consumption and multi-function.

FIG. 1 shows a conventional multi-chip stack package structure. Referring to FIG. 1, a first semiconductor chip 11 is electrically connected to a packaging substrate 10 through a plurality of solder balls 110. A second semiconductor chip 12 is stacked on the first semiconductor chip 11, and a third semiconductor chip 13 is further stacked on the second semiconductor chip 12. The second semiconductor chip 12 and the third semiconductor chip 13 are electrically connected to the packaging substrate 10 through bonding wires 14.

However, to facilitate the process of wire bonding, the second semiconductor chip 12 must be smaller than the first semiconductor chip 11 and the third semiconductor chip 13 must be smaller than the second semiconductor chip 12, thus limiting the number of stacked chips, limiting the electrical functionality and adversely affecting the electrical transmission efficiency of the overall structure.

To improve the electrical functionality and transmission efficiency and meet the demand for function integration of electronic products, TSV (through-silicon via) technology is developed and applied to chip stack package structures.

FIG. 2A is a conventional TSV chip stack package structure. Referring to FIG. 2A, a plurality of stacked TSV chips 21 is electrically connected to a packaging substrate 20 through a plurality of solder balls 201, and a common semiconductor chip 22 is disposed on the top of the TSV chips 21.

However, in such a package structure, heat generated by the TSV chips 21 in the middle of the stack structure is not easily dissipated due to the small spacings between the chips, thus adversely affecting the operation of the TSV chips 21 and even causing damage to the TSV chips 21.

To overcome the above-described drawbacks, referring to FIG. 2B, a metal heat sink 23 is attached to the top surface of the semiconductor chip 22 such that heat generated by the TSV chips 21 in the middle of the stack structure can be transferred to the metal heat sink 23 through the solder balls 201 and the conductive material in the TSVs so as to be dissipated to the outside.

However, such a heat dissipating path is rather long, which leads to a low heat dissipating efficiency. Further, the area of the metal heat sink 23 cannot greatly exceed the area of the semiconductor chip 22 because a too large metal heat sink 23 can cause attaching difficulty and stress problems and even cause cracking of the chip 22.

Therefore, there is a need to provide a multi-chip stack package structure and a fabrication method thereof so as to reduce the fabrication cost, simplify the fabrication process and improve the heat-dissipating efficiency without damaging the heat-dissipating structure of semiconductor chips.

### SUMMARY OF THE INVENTION

Accordingly, the present invention provides a multi-chip stack package structure, which comprises: an inner-layer heat sink having a first surface and a second surface opposite to the first surface, the inner-layer heat sink comprising: a metal plate having a plurality of through holes penetrating therethrough, an oxide layer disposed on the metal plate and on the walls of the through holes, and a plurality of conductive through holes made of a conductive material disposed to the oxide layer of the through holes; a first chip disposed on the first surface of the inner-layer heat sink; and a second chip disposed on the second surface of the inner-layer heat sink.

In the above-described package structure, the second chip can be disposed on the inner-layer heat sink via the top surface thereof, and a circuit board can be further disposed on the bottom surface of the second chip.

In another embodiment, the planar size of the inner-layer heat sink is larger than the area of the first chip such that a portion of the first surface of the inner-layer heat sink is exposed from the first chip, thereby allowing a metal cover to be disposed on the exposed portion of the first surface of the inner-layer heat sink so as to cover the first chip. Further, the second chip can be disposed on the inner-layer heat sink via the top surface thereof, and a circuit board can be further disposed on the bottom surface of the second chip. Furthermore, an encapsulant can be disposed on the circuit board to encapsulate the second chip.

Further, a third chip can be disposed on and electrically connected to the first chip.

The present invention further provides a fabrication method of a multi-chip stack package structure, which comprises the steps of: providing an inner-layer heat sink having a first surface and a second surface opposite to the first surface, wherein fabrication of the inner-layer heat sink comprises the steps of: providing a metal plate and forming a plurality of through holes penetrating the metal plate, forming an oxide layer on the metal plate and on the walls of the through holes, and filling the through holes with a conductive material so as to form a plurality of conductive through holes; and disposing a first chip and a second chip on the first surface and the second surface of the inner-layer heat sink, respectively, and electrically connecting the first chip and the second chip to the conductive through holes of the inner-layer heat sink. Therein, fabrication of the conductive through holes can comprise the steps of: forming a metal layer on the oxide layer and filling the through holes with the metal layer; and removing a portion of the metal layer on the oxide layer and on the ends of the through holes such that the portions of the metal layer in the through holes are exposed from the oxide layer to serve as the conductive through holes.

In the above-described fabrication method, the second chip can be disposed on the inner-layer heat sink via the top surface thereof, and a circuit board can be disposed on the bottom surface of the second chip.

In another embodiment of the fabrication method of the multi-chip stack package structure, the planar size of the inner-layer heat sink is larger than the area of the first chip such that a portion of the first surface of the inner-layer heat sink is exposed from the first chip, thereby, after disposing of the first chip and before disposing of the second chip, a metal cover is disposed on the exposed portion of the first surface of the inner-layer heat sink so as to cover the first chip. Therein, the second chip can be disposed on the inner-layer heat sink via the top surface thereof, and a circuit board can be disposed on the bottom surface of the second chip. The method can further comprise the step of forming an encapsulant on the circuit board to encapsulate the second chip.

In the embodiment wherein the planar size of the inner-layer heat sink is larger than the area of the first chip, fabrication of the inner-layer heat sink comprises the steps of: providing a metal plate and forming a plurality of through holes penetrating the metal plate; forming an oxide layer on a portion of the metal plate and on the walls of the through holes such that a portion of the metal plate is exposed from the oxide layer for disposing of the metal cover; and filling the through holes with a conductive material so as to form the conductive through holes. Further, fabrication of the conductive through holes comprises the steps of: forming a metal layer on the oxide layer and filling the through holes with the metal layer; and removing a portion of the metal layer on the oxide layer and on the ends of the through holes such that the portions of the metal layer in the through holes are exposed from the oxide layer to serve as the conductive through holes

Therefore, the multi-chip stack package structure and the fabrication method thereof according to the present invention involve providing an inner-layer heat sink having two opposite surfaces and a plurality of conductive through holes penetrating the two opposite surfaces, disposing at least a chip on each of the two surfaces of the inner-layer heat sink, and electrically connecting the chips to the conductive through holes. As such, the inner-layer heat sink disposed between the chips provides a heat-dissipating path for rapidly dissipating heat generated by chips in the middle of the package structure, thereby eliminating the need to transfer heat from layer to layer and accordingly improving the heat dissipating efficiency. Further, by using a metal plate having an oxide layer as a heat sink, the rigidity of the overall structure is increased so as to avoid the risk of cracking of the multi-chip stack package structure.

### BRIEF DESCRIPTION OF DRAWINGS

FIG. 1 is a cross-sectional view of a conventional multi-chip stack package structure;

FIGS. 2A and 2B are cross-sectional views of a conventional TSV chip stack package structure, wherein FIG. 2B is another embodiment of the TSV chip stack package;

FIGS. 3A to 3G are cross-sectional views showing a fabrication method of a multi-chip stack package structure according to a first embodiment of the present invention; and

FIGS. 4A to 4I are cross-sectional views showing a fabrication method of a multi-chip stack package structure according to a second embodiment of the present invention.

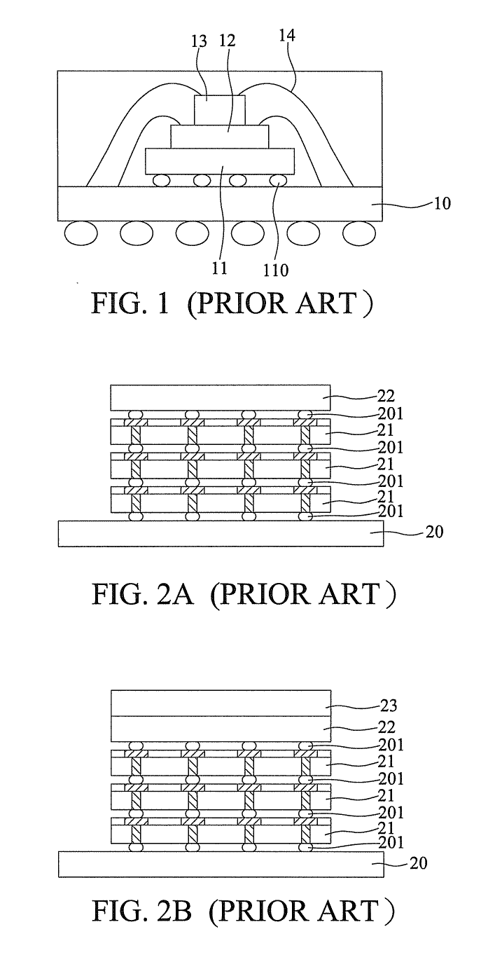

### DETAILED DESCRIPTION OF PREFERRED EMBODIMENTS

The following illustrative embodiments are provided to illustrate the disclosure of the present invention and its advantages, these and other advantages and effects being apparent to those in the art after reading this specification.

It should be noted that the drawings are not intended to limit the present invention. Various modifications and variations can be made without departing from the spirit of the present invention. Further, terms such as “one”, “above”, etc. are merely for illustrative purposes and should not be construed to limit the scope of the present invention.

### First Embodiment

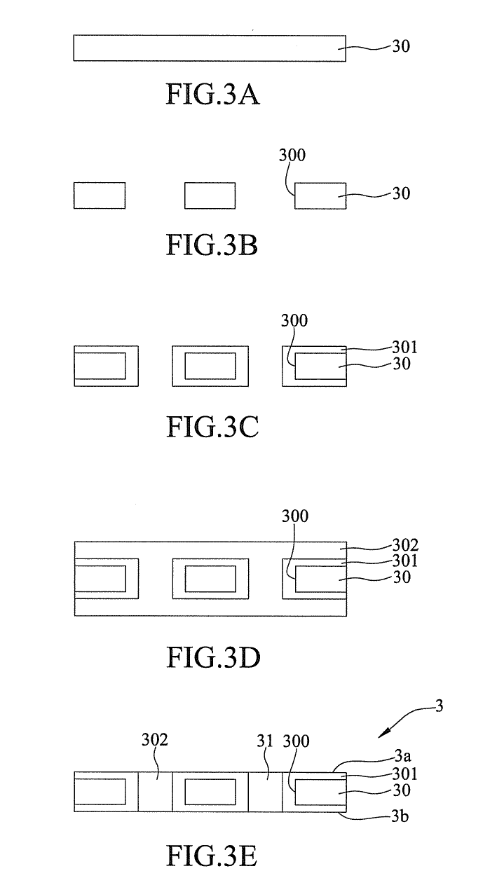

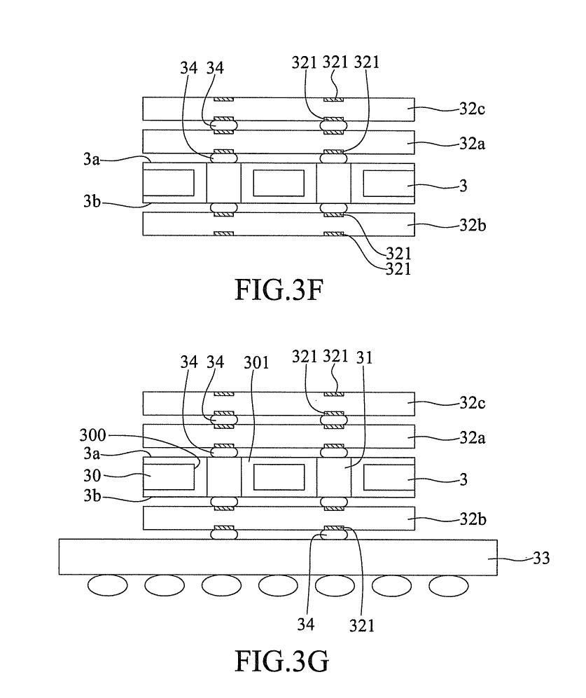

FIGS. 3A to 3G show a fabrication method of a multi-chip stack package structure according to a first embodiment of the present invention. Therein, FIGS. 3A to 3E show fabrication of an inner-layer heat sink 3 (as shown in FIG3E) having a first surface 3a and a second surface 3b opposite to the first surface 3a and a plurality of conductive through holes 31 penetrating the first surface 3a and the second surface 3b.

Referring to FIG. 3A, a metal plate 30 madeof, for example, aluminum is provided.

Referring to FIG. 3B, a plurality of through holes 300 penetrating the metal plate 30 is formed by mechanical drilling or laser drilling

Referring to FIG. 3C, an oxide layer 301 is formed on the metal plate 30 and on the walls of the through holes 300. The oxide layer 301 is made of, for example, aluminum oxide.

Referring to FIGS. 3D and 3E, the through holes 300 are filled with a conductive material so as to serve as conductive through holes 31. Referring to FIG. 3D, a metal layer 302 made of copper is formed on the oxide layer 301 and filled in the through holes 300.

Referring to FIG. 3E, portions of the metal layer 302 on the oxide layer 301 and on the ends of the through holes 300 are removed such that the portions of the metal layer 302 in the through holes 300 are exposed from the oxide layer 301, thus obtaining an inner-layer heat sink 3 having a first surface 3a and a second surface 3b opposite to the first surface 3a and a plurality of conductive through holes 31 penetrating the first surface 3a and the second surface 3b.

Subsequently, referring to FIG. 3F, a first chip 32a and a second chip 32b (each of the first chip 32a and the second chip 32b can be a TSV chip or a chip having circuits disposed on upper and lower surfaces thereof) are disposed on the first surface 3a and the second surface 3b of the inner-layer heat sink 3, respectively, and electrically connected to the conductive through holes 31. In particular, the first chip 32a and the second chip 32b are electrically connected to the conductive through holes 31 of the inner-layer heat sink 3 through metal bumps such as solder balls 34. Generally, each of the first chip 32 and the second chip 32b has a plurality of electrode pads 321 disposed on the top and bottom surfaces thereof. For example, the electrode pads 321 on the bottom surface of the first chip 32a are electrically connected to the conductive through holes 31 of the inner-layer heat sink 3 through the solder balls 34, respectively; and the electrode pads on the top surface of the second chip 32b are electrically connected to the conductive through holes 31 of the inner-layer heat sink 3 through the solder balls 34, respectively. Further, the electrode pads 321 on the top surface of the first chip 32a and the electrode pads 321 on the bottom surface of the second chip 32b can be electrically connected to other electronic components such as circuit boards or chips. The inner-layer heat sink 3 provides a heat-dissipating path for rapidly dissipating heat generated by chips in the middle of the package structure so as to eliminate the need to transfer heat from layer to layer as in the prior art, thereby improving the heat-dissipating efficiency. Further, by using a metal plate having an oxide layer as a heat sink, the rigidity of the overall structure is increased so as to avoid the risk of cracking of the multi-chip stack package structure. Further, a plurality of chips, such as a third chip 32c, can be disposed on and electrically connected to the first chip 32a.

Referring to FIG. 3G, the second chip 32b is disposed on the inner-layer heat sink 3 via the top surface thereof. Further, the bottom surface of the second chip 32b can be disposed on a circuit board 33 via a plurality of solder balls 34. Therein, the circuit board 33 can be a motherboard or a packaging substrate.

According to the above-described fabrication method, the present invention further provides a multi-chip stack package structure having an inner-layer heat sink, which comprises: an inner-layer heat sink 3 having a first surface 3a and a second surface 3b opposite to the first surface 3a and a plurality of conductive through holes 31 penetrating the first surface 3a and the second surface 3b; a first chip 32a disposed on the first surface 3a of the inner-layer heat sink 3; and a second chip 32b disposed on the second surface 3b of the inner-layer heat sink 3.

The inner-layer heat sink 3 comprises: a metal plate 30 made of, for example, aluminum and having a plurality of through holes 300 penetrating therethrough; an oxide layer 301 made of, for example, aluminum oxide and disposed on the metal plate 30 and on the walls of the through holes 300; and a plurality of conductive through holes 31 made of a conductive material such as copper disposed to the oxide layer of the through holes 300.

Further, the first chip 32a and the second chip 32b are electrically connected to the conductive through holes 31 of the inner-layer heat sink 3 through metal bumps. For example, the second chip 32b is disposed on the inner-layer heat sink 3 via the top surface thereof, and the multi-chip stack package structure can further comprise a circuit board 33 disposed on the bottom surface of the second chip 32b. Furthermore, the multi-chip stack package structure can comprise a third chip 32c disposed on and electrically connected to the first chip 32a.

### Second Embodiment

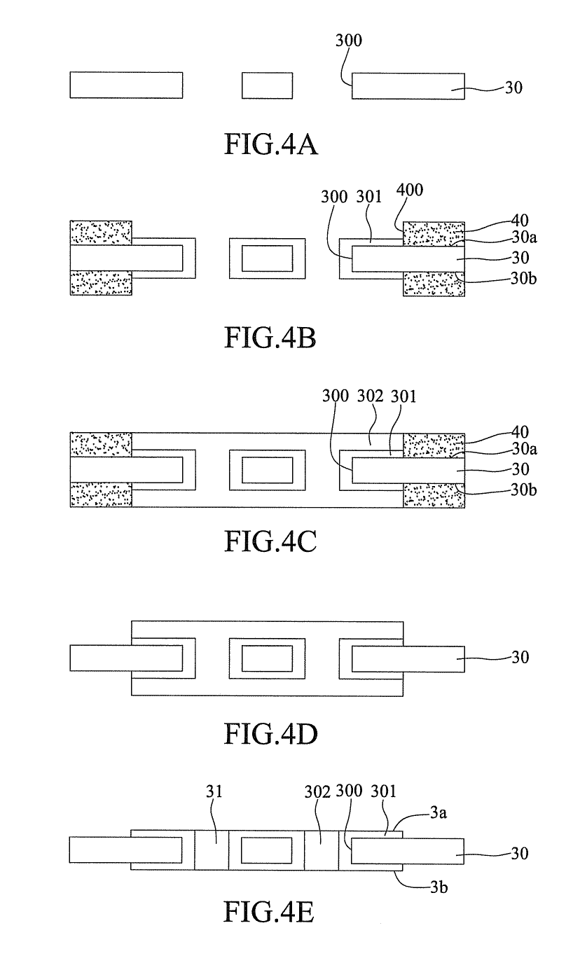

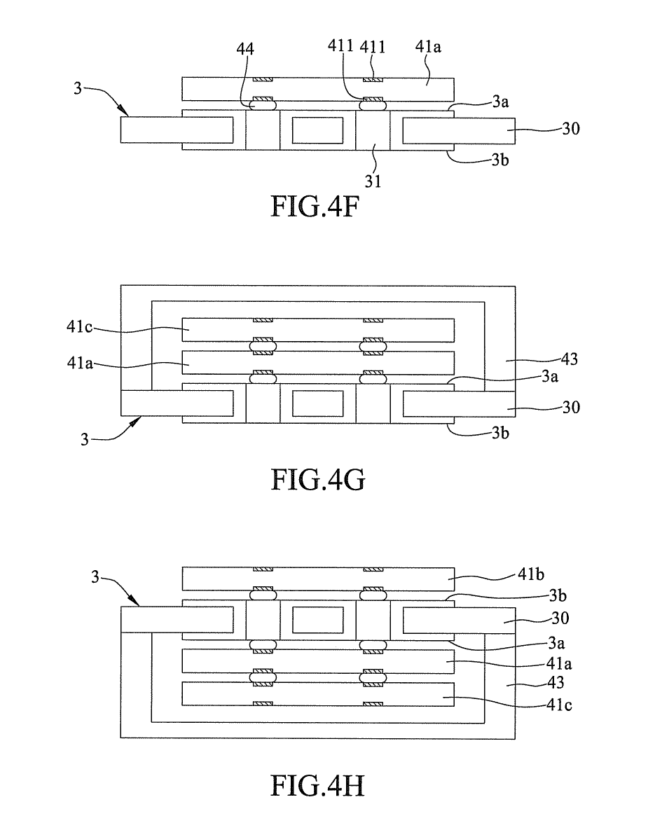

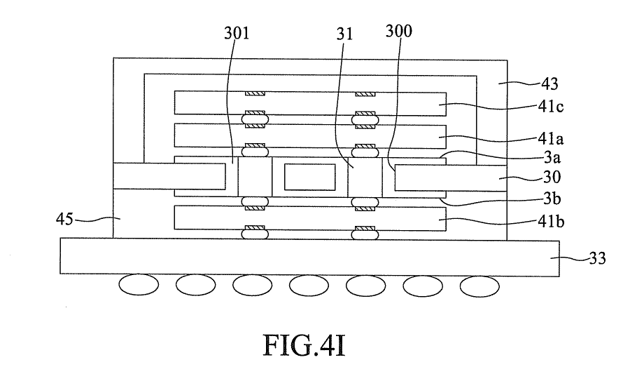

FIGS. 4A to 4I show a fabrication method of a multi-chip stack package structure according to a second embodiment of the present invention. In the present embodiment, the planar size of the inner-layer heat sink is larger than the area of the first chip such that a metal cover can be disposed on the inner-layer heat sink.

FIGS. 4A to 4E show fabrication of the inner-layer heat sink. Referring to FIG. 4A, a metal plate 30 is provided and a plurality of through holes 300 penetrating the metal plate 30 is formed.

Referring to FIG. 4B, an oxide layer 301 is formed on a portion of the metal plate 30 and on the walls of the through holes 300 such that a portion of the metal plate 30 is exposed for disposing of the metal cover. For example, a resist layer 40 is formed around the periphery of the two opposite surfaces 30a, 30b of the metal plate 30, and openings 400 are formed in the resist layer 40 to expose a portion of the metal plate 30 and the conductive through holes 300, and then, an oxide layer 301 is formed on the exposed portion of the metal plate 30 and on the walls of the through holes 300.

Referring to FIGS. 4C to 4E, the through holes 300 are filled with a conductive material so as to serve as conductive through holes 31. Referring to FIG. 4C, a metal layer 302 is formed on the oxide layer 301 and filled in the through holes 300.

Referring to FIG. 4D, the resist layer 40 is removed to expose the periphery of the surfaces of the metal plate 30.

Referring to FIG. 4E, a portion of the metal layer 302 on the oxide layer 301 and on the ends of the through holes 300 is removed such that the portions of the metal layer 302 in the through holes 300 are exposed from the oxide layer 301, thereby obtaining an inner-layer heat sink 3 having a first surface 3a and a second surface 3b opposite to the first surface 3a and a plurality of conductive through holes 31 penetrating the first surface 3a and the second surface 3b.

Referring to FIG. 4F, a first chip 41a is disposed on the first surface 3a of the inner-layer heat sink 3, wherein the first chip 41a has a plurality of electrode pads 411 disposed on two surfaces thereof and electrically connected to the conductive through holes 31 through a plurality of solder balls 44.

Referring to FIG. 4G, a metal cover 43 is disposed on and attached to the portion of the metal plate 30 exposed from the first chip 41a, wherein the metal cover 42 covers the first TSV chip 41a. Further, a plurality of chips such as a third chip 41c can be disposed on and electrically connected to the first chip 41a before the metal cover 43 is disposed on the first chip 41a.

Referring to FIG. 4H, the inner-layer heat sink 3 is turned upside down such that the second surface 3b of the inner-layer heat sink 3 is faced upwards so as to allow a second chip 41b to be disposed thereon. Similar to the first embodiment, the second chip 41b is disposed on the inner-layer heat sink 3 via the top surface thereof.

Referring to FIG. 4I, the bottom surface of the second chip 41b is disposed on a circuit board 33. Further, an encapsulant 45 can be formed on the circuit board 33 to encapsulate the second chip 41b. The encapsulant 45 can be flush with the periphery of the inner-layer heat sink 3 and/or periphery of the circuit board 33.

According to the above-described fabrication method of the present embodiment, the present invention further provides a multi-chip stack package structure having an inner-layer heat sink. The package structure of the present embodiment is similar to that of the first embodiment. A main difference of the present embodiment from the first embodiment is that the planar size of the inner-layer heat sink 3 is larger than the area of the first chip 41a such that a portion of the first surface 3a of the inner-layer heat sink 3 is exposed from the first chip 41a for disposing of a metal cover 43, wherein the metal cover 43 covers the first chips 41a.

The inner-layer heat sink comprises: a metal plate 30 having a planar size larger than the area of the first chip 41a and having a plurality of through holes 300 penetrating the metal plate 30; an oxide layer 301 disposed on a portion of the metal plate 30 and on the walls of the through holes 300 such that a portion of the metal plate 43 is exposed from the oxide layer 301 for disposing of the metal cover 43; and a plurality of conductive through holes 31 made of a conductive material disposed to the oxide layer 301 of the through holes 300.

Similar to the first embodiment, the second chip 41b is disposed on the inner-layer heat sink 3 via the top surface thereof, and the multi-chip stack package structure can further comprise a circuit board 33 disposed on the bottom surface of the second chip 41b. The multi-chip stack package structure can further comprise a third chip 41c disposed on and electrically connected to the first chip 41a; and an encapsulant 45 disposed on the circuit board 33 for encapsulating the second chip 41b.

Therefore, the multi-chip stack package structure and the fabrication method thereof according to the present invention involve providing an inner-layer heat sink having two opposite surfaces and a plurality of conductive through holes penetrating the two opposite surfaces, disposing at least a chip on each of the two surfaces of the inner-layer heat sink, and electrically connecting the chips to the conductive through holes. As such, the inner-layer heat sink disposed between the chips provides a heat dissipating path for rapidly dissipating heat generated by chips in the middle of the package structure, thereby eliminating the need to transfer heat from layer to layer and accordingly improving the heat-dissipating efficiency. Further, by using a metal plate having an oxide layer as a heat sink, the rigidity of the overall structure is increased so as to avoid the risk of cracking of the multi-chip stack package structure.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A multi-chip stack package structure, comprising:
an inner-layer heat sink having a first surface and a second surface opposite to the first surface, comprising: a metal plate having a plurality of through holes penetrating therethrough, an oxide layer disposed on the metal plate and on the walls of the through holes, and a plurality of conductive through holes made of a conductive material disposed to the oxide layer of the through holes;
a first chip disposed on the first surface of the inner-layer heat sink; and
a second chip disposed on the second surface of the inner-layer heat sink.

2. The structure of claim 1, wherein the second chip is disposed on the inner-layer heat sink via the top surface thereof, and a circuit board is disposed on the bottom surface of the second chip.

3. The structure of claim 1, wherein the first and second chips are electrically connected to the conductive through holes of the inner-layer heat sink through a plurality of metal bumps.

4. The structure of claim 1, wherein the planar size of the inner-layer heat sink is larger than the area of the first chip such that a portion of the first surface of the inner-layer heat sink is exposed from the first chip, thereby allowing a metal cover to be disposed on the exposed portion of the first surface of the inner-layer heat sink so as to cover the first chip.

5. The structure of claim 4, wherein the second chip is disposed on the inner-layer heat sink via the top surface thereof, and a circuit board is disposed on the bottom surface of the second chip.

6. The structure of claim 5, further comprising an encapsulant disposed on the circuit board to encapsulate the second chip.

7. The structure of claim 4, further comprising a third chip disposed on and electrically connected to the first chip.

8. The structure of claim 1, wherein the metal plate is made of aluminum, and the oxide layer is made of aluminum oxide.

9. The structure of claim 1, further comprising a third chip disposed on and electrically connected to the first chip.

10. A fabrication method of a multi-chip stack package structure, comprising the steps of:
providing an inner-layer heat sink having a first surface and a second surface opposite to the first surface, wherein fabrication of the inner-layer heat sink comprises the steps of: providing a metal plate and forming a plurality of through holes penetrating the metal plate, forming an oxide layer on the metal plate and on the walls of the through holes, and filling the through holes with a conductive material so as to form a plurality of conductive through holes; and
disposing a first chip and a second chip on the first surface and the second surface of the inner-layer heat sink, respectively, and electrically connecting the first chip and the second chip to the conductive through holes of the inner-layer heat sink.

11. The method of claim 10, wherein fabrication of the conductive through holes comprises the steps of:
forming a metal layer on the oxide layer and filling the through holes with the metal layer; and
removing a portion of the metal layer on the oxide layer and on the ends of the through holes such that the portions of the metal layer in the through holes are exposed from the oxide layer to serve as the conductive through holes.

12. The method of claim 10, wherein the second chip is disposed on the inner-layer heat sink via the top surface thereof, and a circuit board is disposed on the bottom surface of the second chip.

13. The method of claim 10, wherein the first and second chips are electrically connected to the conductive through holes of the inner-layer heat sink through a plurality of metal bumps.

14. The method of claim 10, wherein the planar size of the inner-layer heat sink is larger than the area of the first chip such that a portion of the first surface of the inner-layer heat sink is exposed from the first chip, thereby, after disposing of the first chip and before disposing of the second chip, a metal cover is disposed on the exposed portion of the first surface of the inner-layer heat sink so as to cover the first chip.

15. The method of claim 14, wherein the second chip is disposed on the inner-layer heat sink via the top surface thereof, and a circuit board is disposed on the bottom surface of the second chip.

16. The method of claim 15, further comprising the step of forming an encapsulant on the circuit board to encapsulate the second chip.

17. The method of claim 14, wherein a portion of the metal plate is exposed from the oxide layer for disposing of the metal cover.

18. The method of claim 17, wherein fabrication of the conductive through holes comprises the steps of:
forming a metal layer on the oxide layer and filling the through holes with the metal layer; and
removing a portion of the metal layer on the oxide layer and on the ends of the through holes such that the portions of the metal layer in the through holes are exposed from the oxide layer to serve as the conductive through holes.

19. The method of claim 10, wherein the metal plate is made of aluminum, and the oxide layer is made of aluminum oxide.
